(19) United States
(12) Patent Application Publication
(10) Pub. No.: US 2022/0208585 A1
(43) Pub. Date: Jun. 30, 2022

(54) X-Y Stage

(71) Applicant: Magtronics Technology Inc., Hsinchu County (TW)

(72) Inventor: Yu-Kuang TSENG, Hsinchu County (TW)

(21) Appl. No.: 17/563,082

(22) Filed: Dec. 28, 2021

Related U.S. Application Data
(60) Provisional application No. 63/131,375, filed on Dec. 29, 2020.

(51) Int. Cl. H01L 21/68; H02K 11/21; H02K 41/03; H01L 21/67

(52) U.S. Cl. CPC H01L 21/68; H02K 11/21; H02K 2201/18; H01L 21/67259; H02K 41/031

(57) ABSTRACT

This invention provides an x-y stage includes linear motors, linkages coupled to the linear motors respectively, a decoupling member coupling to the linkages movable in x-y directions freely, and a table fastened to the decoupling member. Coils or armatures of the linear motors can be fastened to the wall of vacuum chamber, such that heats generated in the coils can be conducted outside the vacuum chamber directly through the wall of the chamber. Cables for the coils or armatures are also fastened to the wall of chamber, and particle issue generated by the movable cable in the vacuum chamber can be removed.

### CLAIM OF PRIORITY

This application claims the benefit of priority of U.S. provisional application No. 63/131,375 entitled to inventors filed Dec. 29, 2020 and entitled “X-Y Stage”, the entire disclosures of which are incorporated herein by reference.

### FIELD OF THE INVENTION

The invention relates to a linear motor in vacuum environment, and more particularly to a x-y stage for operating in vacuum environment.

### BACKGROUND OF THE INVENTION

Stages are important tools in the industries. For the current semiconductor manufacturing process, some processes are operated under vacuum environment, such as defect inspection, defect review, and critical dimension (CD) review.

Stages used in the vacuum chamber may face two major issues which include particles and thermal dissipation. The particle issue comes from materials in the vacuum environment will outgas gradually and thus some particles from the materials may be scattered in the vacuum environment. For example, when a screw is driven into a wall for the vacuum chamber, and some particles will inevitably float out some time when the chamber is evacuated. Thus, a designed screw particular for the vacuum chamber is provided. A conductive cable for a movable stage may outgas particles from the encapsulated materials.

The thermal dissipation issue comes from anything generating heats, such as electric motors in the movable stages. The heats generated inside the vacuum chamber will inevitably deteriorate the results of the defect inspection, defect review, and CD review. For example, the defects may be disappeared in the defect inspection or CD may be variant even if the line is straight. Worse, thermal issue may cause a particular position on a wafer different at different temperatures.

A prior art disclosed by Kidron in U.S. Pat. No. 8,763,999 provides low out-gassing materials to enclose all high out-gassing materials of the stage used in the vacuum environment to avoid the particle issue. An example is to use bellow with low out-gassing materials to enclose cables for the coils of the linear motor, wherein the cables are always high out-gassing.

However, cables for the linear motor are always thick to provide enough currents for the coils or armatures of the linear motors, and the bellow for enclosing the cables will therefore increase its length and cross-sectional area. The bellow, even if is low out-gassing, will rub itself while the table moves. Thus, the particle issue is still there.

Furthermore, a complex cooling system is provided to cooldown heats generated in the coils, so the bellow will not only enclose the cables but also cooling tube. Hence, the length and the cross-sectional area of the bellow will further increase to deteriorate the particle issue while the table moves. In general, the x-y stage will use two bellows, and the particle issue will double.

Because loading of x-stage is different from loading of y-stage, curve motion of this x-y stage can't be accurate.

Thus, an invention is necessary to solve the issues mentioned above.

### BRIEF SUMMARY OF THE INVENTION

The object of this invention is to provide a x-y stage movable in vacuum environment.

In the present invention, no movable cable is provided for linear motors which generate less particles in the vacuum environment.

In the present invention, heats generated by cables or coils can be transferred outside directly by thermal conduction through the walls of vacuum chamber. Thus, there is no cooling system for the cables or coils.

In the present invention, a thinner stage is provided due to only one table is provided.

In the present invention, loads of the linear motors in two directions orthogonal with each other are very close with each other, and there is no cross-loading for the counter linear motor. The nature frequencies of the two linear motors are very close, and response of the linear motors in the two directions are close, thereby improving interpolation motion of the table. The accuracy of curve motion of the x-y stage can be enhanced further.

Accordingly, the invention provides a linear motor in a vacuum chamber, which comprises a stator fastened to a wall of the chamber and configured by a plurality of coils which is arranged along a first direction, and a mover, coupled to the stator, being configured by a plurality of magnets and moving along the first direction, wherein heats generated by the plurality of coils are conducted outside the vacuum chamber through the wall.

The present invention also provides a monitoring device for measuring the linear motor, which comprises a scale fastened on the mover, and a read head fastened on the wall to read the scale such that a position of the mover can be obtained.

The present invention further provides a stage in a chamber, which comprises a first linear motor fastened to the chamber, a first linkage coupled to the first linear motor, a second linear motor fastened to the chamber, a second linkage coupled to the second linear motor, a decoupling member coupled to the first linkage and the second linkage, and a table fastened to the decoupling member. The first linear motor provides a first movement along a first direction, and the first linkage moves in the first direction. The second linear motor provides a second movement along a second direction orthogonal to the first direction, and the second linkage moves along the second direction. The decoupling member can be moved in the first direction and the second direction.

The stage according to the present invention, the decoupling member includes a body with a first opening and a second opening, such that the first linkage passes through the first opening and the second linkage passes through the second opening.

The stage according to the present invention, wherein the first linear motor includes first coils as a first stator fastened to a first high thermal conductive material, and the second linear motor includes second coils as a second stator fastened to a second high thermal conductive material.

The stage according to the present invention, the chamber includes the first high thermal conductive material and the second high thermal conductive material fastened to the chamber.

The stage according to the present invention, the chamber is a vacuum chamber and heats generated by the first and second stators are conducted outside the chamber through the first second, third, and fourth walls.

The stage according to the present invention, the first linear motor includes a first mover configured by a first plurality of magnets, and the second linear motor includes a second mover configured by a plurality of magnets.

The stage according to the present invention, the first linkage couples to the first mover, and the second linkage couples to the second mover.

The stage according to the present invention further comprises a z-stage on the table.

The stage according to the present invention further comprises a theta stage on the table.

The stage according to the present invention further comprises an electrostatic chuck on the table.

The stage according to the present invention further comprises a jig on the table.

The present invention still provides a stage in a vacuum chamber, which comprises a first linear motor and a second linear motor providing a first movement along a first direction, a first linkage coupled to a first mover of the first linear motor and a second mover of the second linear motor, a third linear motor and a fourth linear motor providing a second movement along a second direction orthogonal to the first direction, a second linkage coupled to a third mover of the third linear motor and a fourth mover of the fourth linear motor, a decoupling member coupled to the first linkage and the second linkage, and a table fastened to the decoupling member. The first linear motor and the second linear motor include a first plurality of coils fastened on a first wall of the vacuum chamber and a second plurality of coils fastened on a second wall of the vacuum chamber respectively. The third linear motor and the fourth linear motor including a third plurality of coils fastened on a third wall of the vacuum chamber and a fourth plurality of coils fastened on a fourth wall of the vacuum chamber respectively.

The stage according to the present invention, the first linear motor, the second linear motor, the third linear motor, and the fourth linear motor include a first fixed rail and a first slider thereon, a second fixed rail and a second slider thereon, a third fixed rail and two third sliders thereon, and a fourth fixed rail and two fourth sliders thereon respectively.

The stage according to the present invention, one end of the first linkage fastens to one side of the first slider and a first mover of the first linear motor fastens to the other side of the first slider, and the other end of the first linkage fastens to one side of the second slider and a second mover of the second linear motor fastens to the other side of the second slider.

The stage according to the present invention, each of the two third sliders has one side fastened to two third movers of the third linear motor respectively and has the other side fastened to one end of the second linkage, and each of the two fourth sliders has one side fastened to two fourth movers of the third linear motor respectively and has the other side fastened to the other end of the second linkage.

The stage according to the present invention, the second linkage includes a first arm and a second arm parallel with each other.

The stage according to the present invention, the decoupling member includes a first decoupling rail, fastened to the first linkage and moveable along the first direction, a first decoupling slider moving freely on the first decoupling rail, a first decoupling linkage fastened on the first decoupling slider, a second decoupling rail and a third decoupling rail fastened on the first arm and the second arm respectively and both moveable along the second direction, a second decoupling slider and a third decoupling slider moving on the second decoupling rail, and a fourth decoupling slider and a fifth decoupling slider on the third decoupling rail, a second decoupling linkage and a third decoupling linkage fastened on the second decoupling slider and the third decoupling slider respectively, and a fourth decoupling linkage and a fifth decoupling linkage fastened on the fourth decoupling slider and the fifth decoupling slider respectively. The first decoupling rail provides the second movement along the second direction. The second decoupling rail and a third decoupling rail provides the first movement along the first direction.

The stage according to the present invention, the table fastens to the first decoupling linkage, the second decoupling linkage, the third decoupling linkage, the fourth decoupling linkage, and the fifth decoupling linkage.

The stage according to the present invention, the decoupling member includes a first decoupling rail coupled to said first linear motor and said second linear motor, a first decoupling slider on the first decoupling rail, a first decoupling linkage fastened on the first decoupling slider, a second decoupling rail coupled to said third linear motor and said fourth linear motor, a second decoupling slider on the second decoupling rail, and a second decoupling linkage fastened on the second decoupling slider. The first decoupling rail is moveable along the first direction, and the first decoupling slider is moveable along the second direction. The second decoupling rail is moveable along the second direction, and the second decoupling slider is moveable along the first direction.

The stage according to the present invention, the first linkage includes a first arm and a second arm parallel with each other.

The stage according to the present invention, the decoupling member includes a first decoupling rail and a second decoupling rail fastened to the first arm and the second arm respectively and movable along the first direction, a first decoupling slider and a second decoupling slider moving freely on the first decoupling rail and the second decoupling rail respectively, a first decoupling linkage fastened on the first decoupling slider, and a second decoupling linkage on the second decoupling slider. The first decoupling rail and a second decoupling rail provide the second movement along the second direction.

The stage according to the present invention, the second linkage includes a third arm and a fourth arm parallel with each other.

The stage according to the present invention, the decoupling member includes a third decoupling rail and a fourth decoupling rail fastened on the third arm and the fourth arm respectively and both moveable along the second direction, a third decoupling slider and a fourth decoupling slider moving on the third decoupling rail and the fourth decoupling rail respectively, and a third decoupling linkage and a fourth decoupling linkage fastened on the third decoupling slider and the fourth decoupling slider respectively. The third decoupling rail and a fourth decoupling rail provides the first movement along the first direction.

The stage according to the present invention, the table fastens to the first decoupling linkage, the second decoupling linkage, the third decoupling linkage, and the fourth decoupling linkage.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

Further advantages of the present invention may become apparent to those skilled in the art with the benefit of the following detailed description of the preferred embodiments and upon reference to the accompanying drawings in which:

FIG. 1 is a schematic top-view illustration of an x-y stage in according to one embodiment of the present invention;

FIG. 2 is a schematic oblique-view representation of a linear motor in according to one embodiment of the present invention;

FIG. 3A is a schematic cross-view illustration of a linear motor in according to one embodiment of the present invention;

FIG. 3B is a schematic cross-view illustration of a linear motor in according to another embodiment of the present invention;

FIGS. 4A and 4B are schematic oblique-view representations of decoupling means in accordance with one embodiment of the present invention;

FIG. 5 is a schematic oblique-view representation of decoupling means in accordance with another embodiment of the present invention;

FIG. 6A is a schematic top-view illustration of an x-y stage with a first decoupling members configured on two linear motors in according to one embodiment of the present invention;

FIG. 6B is a schematic cross-sectional view illustration of the x-y stage with the first decoupling members configured on the two linear motors in accordance with the embodiment in FIG. 6A of the present invention;

FIG. 7A is a schematic top-view illustration of an x-y stage with a second decoupling members configured on another two linear motors in according to one embodiment of the present invention;

FIG. 7B is a schematic cross-sectional view illustration of the x-y stage with the second decoupling members configured on the two linear motors in accordance with the embodiment in FIG. 7A of the present invention;

FIG. 8A is a schematic top-view illustration of an x-y stage with several decoupling linkages configured on all decoupling rails in according to one embodiment of the present invention;

FIG. 8B is a schematic cross-sectional view illustration of the x-y stage with several decoupling linkages configured on the decoupling rails in accordance with the embodiment in FIG. 8A of the present invention;

FIG. 9A is a schematic top-view illustration of an x-y stage with a table mounted on the decoupling linkages in according to one embodiment of the present invention;

FIG. 9B is a schematic cross-sectional view illustration of the x-y stage with a table mounted on the decoupling linkages in accordance with the embodiment in FIG. 9A of the present invention;

FIG. 10A is a schematic top-view illustration of an x-y stage with a first linkage configured on two linear motors in accordance with another embodiment of the present invention;

FIG. 10B is a schematic top-view illustration of the x-y stage with a first decoupling member configured on the first linkage in accordance with another embodiment of the present invention;

FIG. 10C is a schematic top-view illustration of the x-y stage with a second linkage configured on another two linear motors in accordance with another embodiment of the present invention;

FIG. 10D is a schematic top-view illustration of the x-y stage with a second decoupling member configured on the second linkage in accordance with another embodiment of the present invention;

FIG. 11 is a schematic cross-sectional view illustration of some other stages mounted on the table in accordance with one embodiment of the present invention;

FIG. 12 is a schematic cross-sectional view illustration of jig configured on the table in accordance with one embodiment of the present invention;

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

Various example embodiments of the present invention will now be described more fully with reference to the accompanying drawings in which some example embodiments of the invention are shown. Without limiting the scope of the protection of the present invention, all the description and drawings of the embodiments will exemplarily be referred to. However, the embodiments are not be used to limit the present invention to x-y stage.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention.

In this invention, the term “vacuum” refers to space devoid of matter, wherein space is encapsulated in a chamber. The pressure ranges of vacuum depend upon the application of the stage.

In this invention, the term “particles” refers to nano-particles or micro-particles in the vacuum chamber.

In this invention, the term “linear motor” refers to a motor which provides a linear motion or movement.

In this invention, the term “stator” refers to a stationary part of the linear motor.

In this invention, the term “coils” or “armature” refers to parts for generating electric and magnetic field in the linear motors by electric currents. In the present invention, a stator is configured by a plurality of coils or armatures in a linear motor.

In this invention, the term “mover” refers to a moving component of the linear motor.

In this invention, the term “magnets” refers to objects which produce magnetic field. The magnets in the present invention are forced by magnetic fields provided the coils or armatures in the linear motors. In the present invention, a mover is configured by a plurality of magnets in a linear motor.

In this invention, the term “rail” refers to a structure wherein an object thereon can be moved along the rail only.

In this invention, the term “slider” refers to an object freely moving on the rail, and the slider has shapes engaged with the rail.

In this invention, the term “linkage” refers to a rod or bar, or a structure which provides a support between two objects at the two ends of the linkage.

In this invention, the term “decoupling” refers to eliminates the interrelationship between two separate objects. In this invention, the term “decoupling member” refers to an object which eliminates the interrelationship between two separate objects.

In this invention, the term “decoupling rail” refers to a rail in a decoupling member.

In this invention, the term “decoupling slider” refers to a slider moving freely on the decoupling rail in a decoupling member.

In this invention, the term “decoupling linkage” refers to a structure for supporting or connecting objects in a decoupling member.

In this invention, the term “encoder” refers to an object for monitoring and measuring positions of an object.

In this invention, the term “scale” refers to a ruler of the encoder which fastens on a sample such that a position of the sample can be reported by the encoder.

In this invention, the term “read head” refers to a sensor for reading position on the scale.

In this invention, the term “table” refers to a plain plate which a sample or object can be configured thereon.

In this invention, the term “stage” refers to a system for precisely controlling sample on the stage with a specific motion. An x-y stage, in the present invention, provides a precise motion in x-y directions.

In the drawings, relative dimensions of each component and among every component may be exaggerated for clarity. Within the following description of the drawings the same or like reference numbers refer to the same or like components or entities, and only the differences with respect to the individual embodiments are described.

In the present invention, coils or armatures of a linear motor are arranged or configured along walls of the vacuum chamber, and heats generated by the coils can be conducted or dissipated outside the vacuum chamber through the walls directly. The walls of the vacuum chamber should be high thermal conductivity.

In the present invention, heats generated by coils or armatures of the linear motor can be dissipated through high thermal conductive materials, such as water cooler or Cu, Al, brass, polycrystalline diamond, SiC ceramic, SiN ceramic, Beryllium Oxide, AlN ceramics, or combination thereof. All high thermal conductive material will directly contact walls of the vacuum chamber.

In the present invention, cables for the coils or armatures can be fastened to the wall of the vacuum chamber. Coils or armatures are stators and magnets are movers.

In the present invention, linkages or rods are coupled to the movers and movable with the movers. Rails and sliders are provided to the linear motor.

In the present invention, decoupling member coupled to the two linkages, such that the decoupling member can be moved in two orthogonal directions freely. Cross-sectional shape must comply with the decoupling member.

In the present invention, a table is fastened to the decoupling device, so the table can be moved in the two orthogonal directions controlled by two linear motors. A z-stage can be mounted on the table, and an example of z-stage is actuated by piezoelectric material. The current for driving the z-stage is too small to incur particle issue while the table moves, because the cable for the z-stage can be thin enough.

In the present invention, a theta stage can be mounted on the z-stage or table. The current for driving the theta stage is too small to incur particle issue also while the table moves or rotates, because the cable for the theta stage can be thin enough.

In the present invention, an electrostatic chuck (E-chuck) can be mounted on the theta stage or z-stage. The current for driving the E-chuck is also small not to incur particle issue while the table moves, because the cable for the E-chuck can be thin enough.

In the present invention, encoder includes a scale, and a read head, wherein the scale is fastened on the wall while the read head is always fastened on the mover. The current for driving the read head is small and cable for the read head is thin also, thereby generating lower heats in the cable. Thus, the particle issue is not significant in general.

However, if the vacuum requirement is ultrahigh, the scale can be fastened to the mover, such that cables for the read head can be fastened to the wall of the vacuum chamber.

Turning now to the drawings, it is noted that the figures are not drawn to scale. In particular, the scale of some of the elements of the figures is greatly exaggerated to emphasize characteristics of the elements. Elements shown in more than one figure that may be similarly configured have been indicated using the same reference numerals.

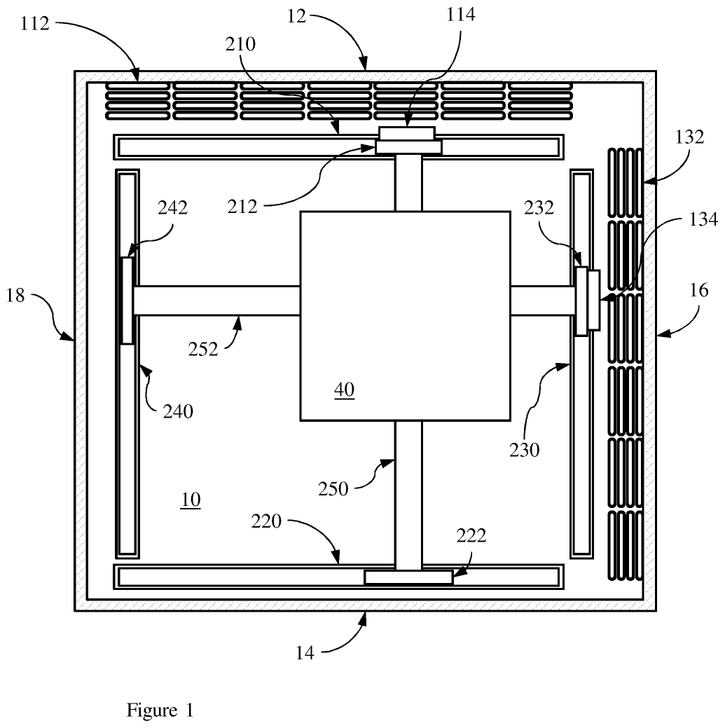

Please refer to FIG. 1, wherein a vacuum chamber 10 is provided. Peripherals of vacuum chamber 10 are enclosed by the four walls 12/14/16/18, while the bottom and top parts are not shown for clarity. Two linear motors include coils 112 and 132 and magnets 114 and 134, respectively. Coils 112 and 132 of linear motors are fastened and directly contact to the walls 12 and 16 respectively. Magnets 114 and 134 are fastened to the sliders 212 and 222 respectively, while the sliders 212 and 222 can be moved along the rails 210 and 220 freely. A linkage 250 is coupled to the sliders 212 and 222 for moving in the first direction, and a linkage 252 is coupled to the sliders 232 and 242 for moving in the second direction which orthogonal to the first direction. In this invention, the first direction may be the x-direction, while the second direction may be the y-direction, or vice versa. A decoupling member under the table 40 will couple the two linkages 250 and 252. The table 40 is fastened to the decoupling member.

In this embodiment, all cables for the coils are fastened on the walls. However, there is eccentric motion due to only one linear motor for driving the table in one direction.

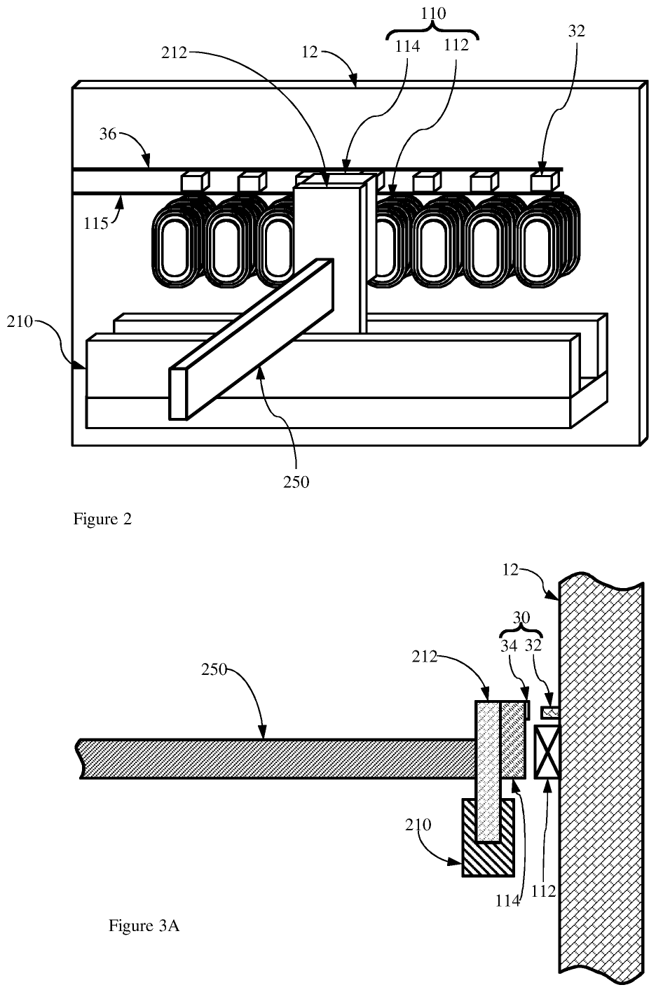

Please refer to FIG. 2, wherein an embodiment of a linear motor 110 coupled with wall 12 and linkage 250 is shown. The linear motor 110 includes coils 112, a plurality of magnets 114, a rail 210, and a slider 212. Coils 112, as a stator, are fastened on the wall 12 of chamber such that heats generated by the coils 112 can be thermal conducted outside the vacuum chamber through the wall 12. The plurality of magnets 114, as a mover, is fastened on a slider 212 moveable along the rail 210. A cable 115, for driving the coils 112, is fastened on the wall 12.

A plurality of read heads 32, fastened on the wall 12, monitor the position of the slider 212. A cable 36, for driving the plurality of read heads 32, is fastened on the wall 12. A linkage 250, fastened to the slider 212, moves along a first direction defined by the rail 210.

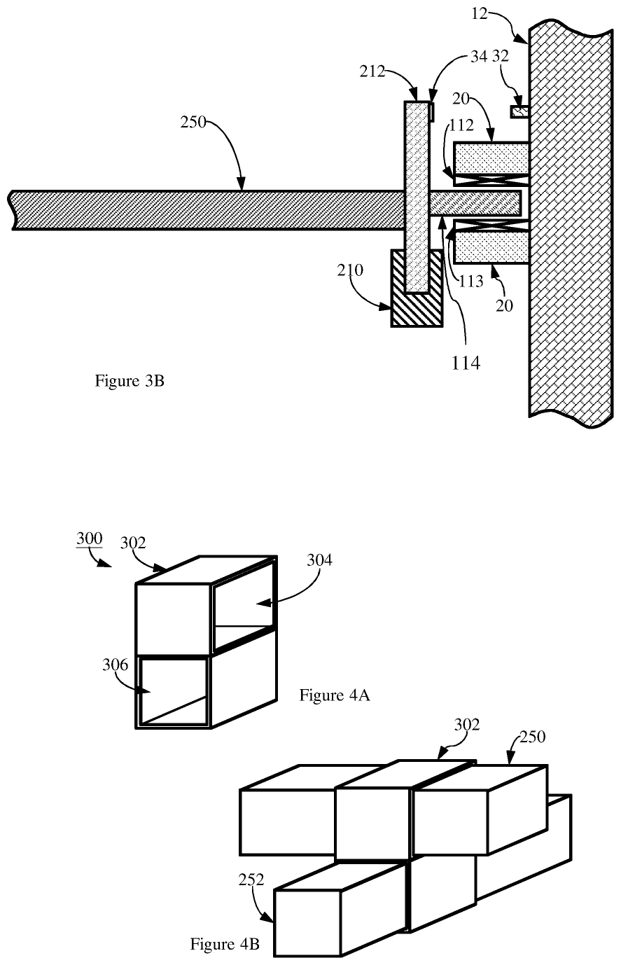

Please refer to FIG. 3A, wherein a cross-sectional view of one embodiment shown in FIG. 2 is illustrated. An encoder 30 includes a read head 32 and a scale 34, wherein the read head 32 is fastened on the wall 12 and the scale 34 is fastened on the magnet 114. The read head 32 will read the position information on the scale 34, and hence, the position of the slider 212 can be monitored accurately.

Please refer to FIG. 3B, wherein a cross-sectional view of another embodiment shown in FIG. 2 is illustrated. If the vacuum chamber is too large to fasten the coils of the linear motor on the chamber wall, the coils or armatures can be fastened to a high thermal conductive material 20 first, and the high thermal conductive material 20 is fastened to the chamber wall 12. In this embodiment, coils or armatures 112 and 113 are fastened to the high thermal conductive material 20. Then, coils or armatures 112 and 113 can be configured in horizontal, and the plurality of magnets 114 can be sandwiched by the coils or armatures 112 and 113. Scale 34 can be fastened on the slider 212.

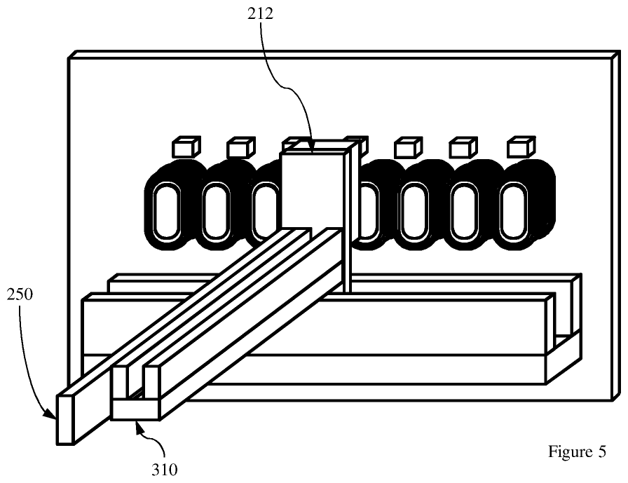

Please refer to FIG. 4A and FIG. 4B, wherein an embodiment of decoupling member 300 is introduced. The decoupling member 300 includes a body 302 and two openings 304 and 306. The first opening 304 is adapted for the linkage 250 for moving the decoupling member 300 in the first direction, and the second opening 306 is adapted for the linkage 252 for moving the decoupling member 300 in the second direction.

Another embodiment of the decoupling member includes at least two decoupling rails respectively in the first direction and in the second direction orthogonal to the first direction, at least two sliders on the two decoupling rails respectively, and at least two decoupling linkages on the two decoupling sliders respectively. Please refer to FIG. 5, wherein the decoupling rail 310 can be adjacent to the linkage 250 or on the linkage 250. In this embodiment, the rail 310 fastened to the slider 212. Moreover, decoupling member includes a first decoupling rail moveable in y direction and driven by a y linear motors, which provides a free movement in x direction; a second decoupling rail moveable in x direction and driven by an x linear motors, which provides a free movement in y direction. Furthermore, decoupling member includes a first slider on the first decoupling rail and freely moveable along the x direction, and a second slider on the second decoupling rail and freely moveable along the y direction. The table will fasten to the first decoupling slider through a first decoupling linkage and to the second decoupling slider through a second decoupling linkage. The first decoupling rail and the second decoupling rail are not coupled with each other.

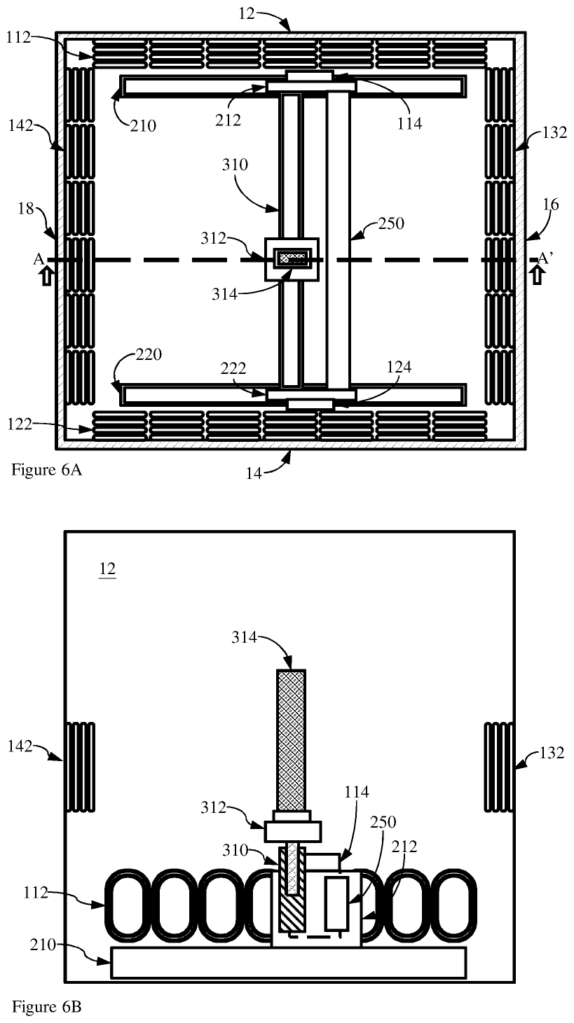

The following will detail several embodiments of the decoupling member with the drawings. Please refer to FIG. 6A and FIG. 6B, wherein the former is a top view and the latter is a cross-sectional view in the AA′ line of the FIG. 6A. In this embodiment, two linear motors for driving a table in one direction will provide better loading to the table. The four coils 112/122/132/142 are fastened to the walls 12/14/16/18 respectively. The height of the coils 132 and 142 is higher than that of the coils 112 and 132. The first rail 210 is configured below the first coils 112 such that a first slider 212 movable in the first rail 210 can face to the first coils 112. A first plurality of magnets 114 fastened to the first coils 212 as a mover. The second rail 220 is configured below the second coils 122 such that a second slider 222 movable in the second rail 220 can face to the second coils 122. A second plurality of magnets 124 fastened to the second coils 222 as a mover. The first rail 210 and the second rail 220 provides the first slider 212 and the second slider 222 movable in a first direction.

Two ends of a first linkage 250 are fastened to the first slider 212 and second slider 222, and hence the linkage 250 is movable in the first direction. Two ends of a first decoupling rail 310 are fastened to the first slider 212 and the second slider 222, hence the first decoupling rail 310 per se can be movable in the first direction. The purpose of the first linkage 250 provides suitable support for the first decoupling rail 310, and hence the first decoupling rail 310 can be configured on or adjacent to the first linkage 250. Moreover, the decoupling rail 310 can be fastened to the first linkage 250. A first decoupling slider 312 is movable on the first decoupling rail 310 along a second direction orthogonal to the first direction. A first decoupling linkage 314 is fastened on the first decoupling slider 312. All movers are fastened to the sliders respectively.

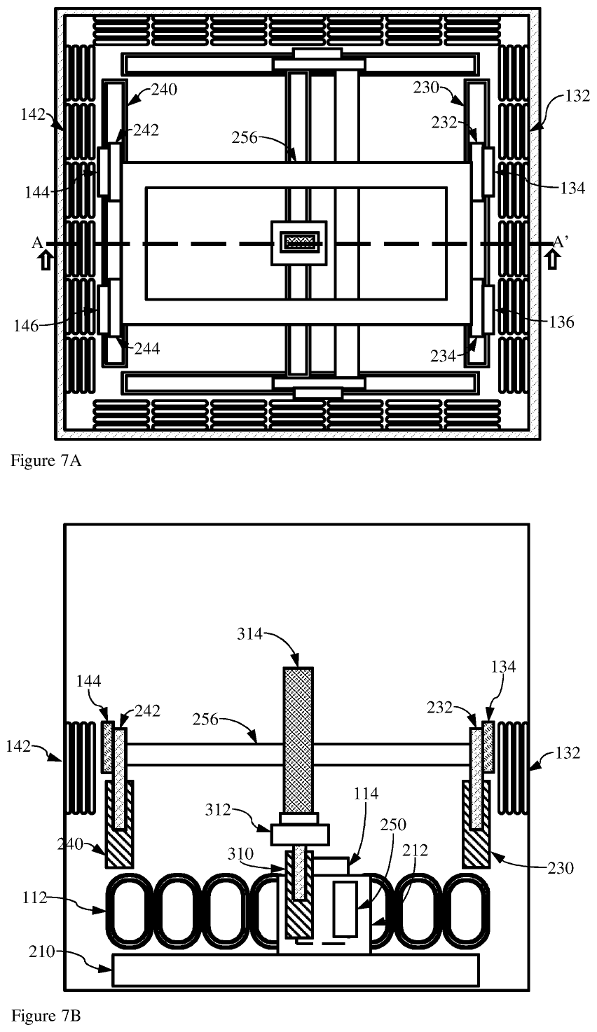

Please refer to FIG. 7A and FIG. 7B, wherein a third rail 230 is configured below the third coils 132 such that a third slider 232 and a fourth slider 234 movable in the third rail 230 can face to the third coils 132. A third plurality of magnets 134 and a fourth plurality of magnets 136 fastened to the third coils 232 as two movers respectively. The fourth rail 240 is configured below the fourth coils 142 such that a fifth slider 242 and a sixth slider 244 movable in the fourth rail 240 can face to the fourth coils 142. A fifth plurality of magnets 144 and a sixth plurality of magnets 146 fastened to the fourth coils 242 as two movers respectively. The third rail 230 provides the third slider 232 and the fourth slider 234 movable in the second direction. The fourth rail 240 provides the fifth slider 242 and the sixth slider 244 movable in the second direction also. All movers are fastened to the sliders respectively.

In this embodiment, a second linkage 256, with two arms, has an opening suitable for the decoupling linkage 314 movable thereinside. One end of the second linkage 256 fastens to the third slider 232 and the fourth slider 234, and the other end of the second linkage 256 fastens to the fifth slider 242 and the sixth slider 244. Hence, the second linkage 256 is movable in the second direction.

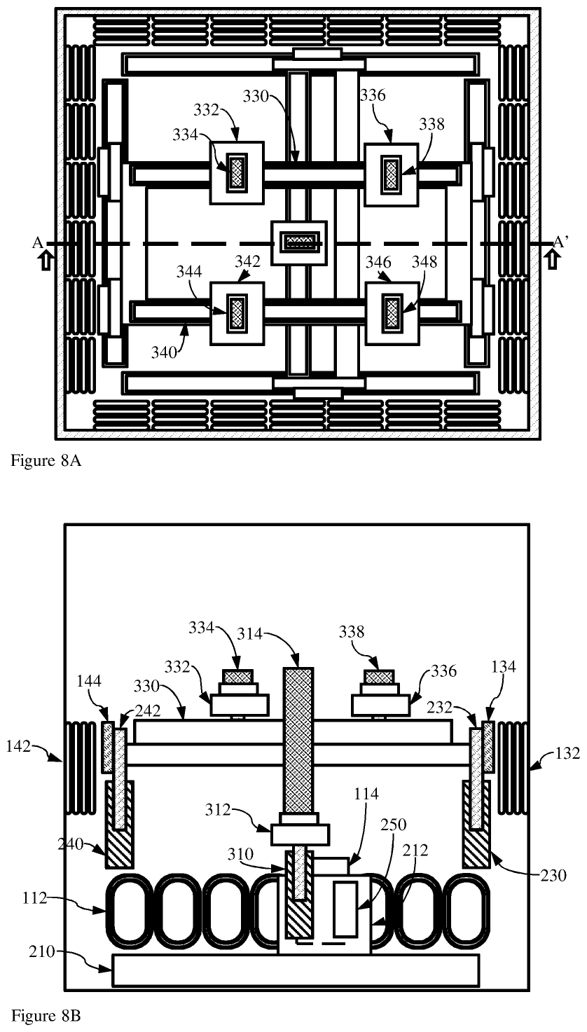

Please refer to FIG. 8A and FIG. 8B, wherein two decoupling rails 330 and 340 are fastened to the second linkage 256. A second decoupling rail 330 fastens on one arm of the second linkage 256 and a third decoupling rail 340 fastens on the other arm of the second linkage 256. A second decoupling slider 332 and a third decoupling slider 336 are movable on the second decoupling rail 330 along the first direction. A second decoupling linkage 334 and a third decoupling linkage 338 are fastened to the second decoupling slider 332 and the third decoupling slider 336 respectively. A fourth decoupling slider 342 and a fifth decoupling slider 346 are movable on the third decoupling rail 340 along the first direction. A fourth decoupling linkage 344 and a fifth decoupling linkage 348 are fastened to the fourth decoupling slider 342 and the fifth decoupling slider 346 respectively. Please also notice in a preferred embodiment that the top surface of the first decoupling linkage 314, the second decoupling linkage 334, the third decoupling linkage 338, the fourth decoupling linkage 344, and the fifth decoupling linkage 348 should be at the same height.

In this embodiment, the first decoupling rail 310 is not coupled to the second decoupling rail 330 and the third decoupling rail 340, and the decoupling member includes decoupling rails 310/330/340, decoupling sliders 312/332/336/342/346, and decoupling linkages 314/334/338/344/348.

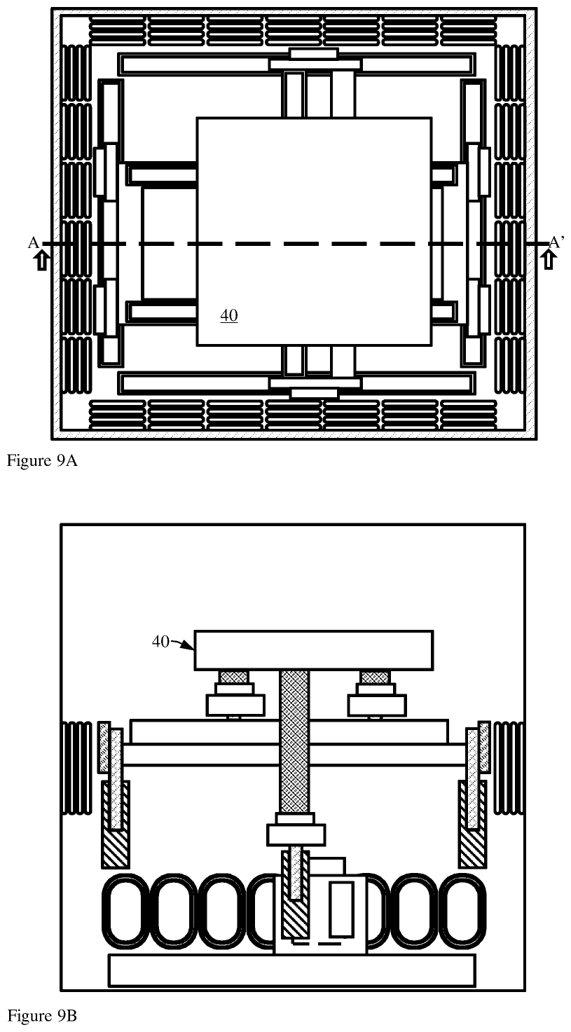

Please refer to FIGS. 9A and 9B, wherein a table 40 is fastened to the first decoupling linkage 314, the second decoupling linkage 334, the third decoupling linkage 338, the fourth decoupling linkage 344, and the fifth decoupling linkage 348. Thus, the table 40 can be movable in the first direction and second direction. Please also notice that the first decoupling rail 310 is not coupled to the second decoupling rail 330 and the third decoupling rail 340; that's why the table 40 can be moved by the two linear motor independently. When the first linear motor and the second linear motor provide the table 40 moving in the first direction through the first decoupling linkage 314, the table 40 is freely movable along the second direction on the second decoupling rail 330 and the third decoupling rail 340. On the other hand, when the third linear motor and fourth linear motor provide the table 40 moving in the second direction through the second decoupling linkage 334, the third decoupling linkage 338, the fourth decoupling linkage 344, and the fifth decoupling linkage 348, the table 40 is freely movable along the first direction on the first decoupling rail 310. Thus, the loading of the first and second linear motors to the table 40 can be designed equal to that of the third and fourth linear motors. Compared to the conventional x-y stage, there are two tables, wherein a first table is mounted on the second table. Thus, a linear motor for driving the second table will incur loading of the first table and another linear motor for driving the first table.

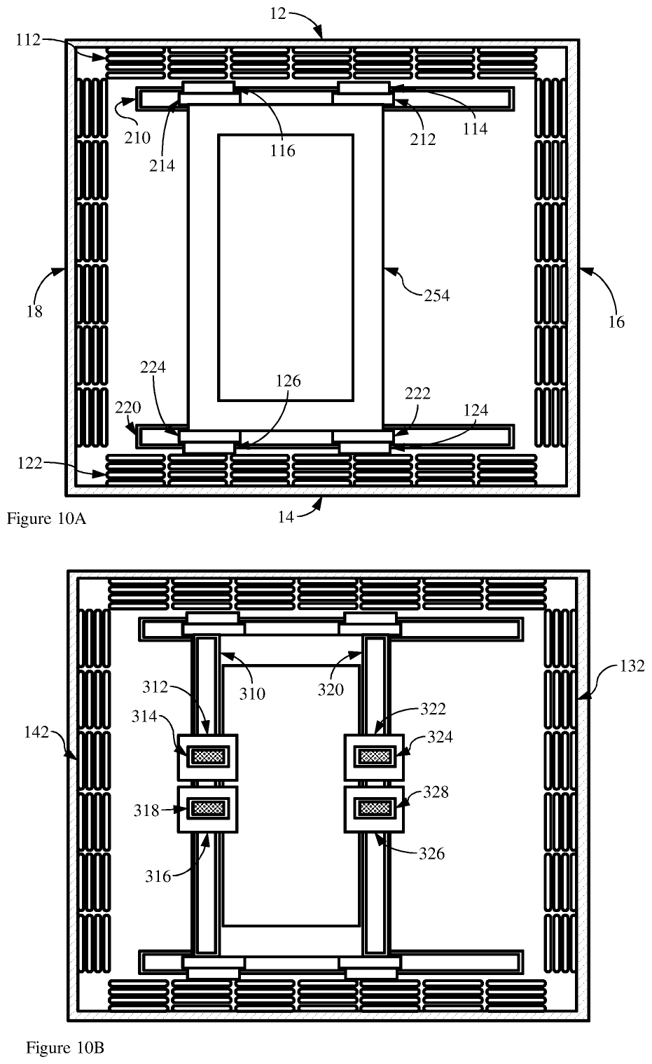

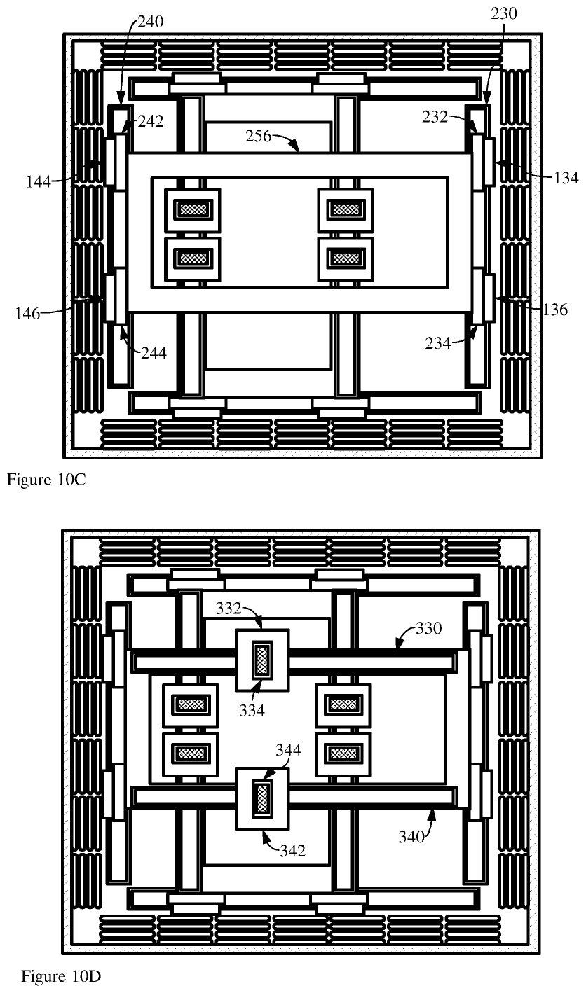

In the previous embodiment, there is only one decoupling rail movable along the first direction. This design is suitable for the vacuum chamber is small. However, if the vacuum chamber has enough space, there should be two decoupling rails movable in each direction. Please refer to FIG. 10A, wherein two linear motors are provided for a first linkage movable along the first direction. A first rail 210 is below the first coils 112 and the second rail 220 is below the coils 122. A first slider 212 and a second slider 214 are movable on the first rail 210. A first plurality of magnets 114 and a second plurality of magnets 116, facing to the first coils 112, fasten to the first slider 212 and the second slider 214 respectively. A third slider 222 and a fourth slider 224 are movable on the second rail 220. A third magnet 124 and a fourth magnet 126, facing to the second coils 122, fasten to the third slider 222 and the fourth slider 224 respectively. A first linkage 254, with two arms, has an opening. One end of the first linkage 254 fastens to the first slider 212 and the second slider 214, and the other end of the first linkage 254 fastens to the third slider 222 and the fourth slider 224.

Please refer to FIG. 10B, wherein two decoupling rails are mounted on the first linkage 254. The first decoupling rail 310 is mounted on one are of the first linkage 254 and the second decoupling rail 320 is mounted on the other arm of the first linkage 254. A first slider 312 and a second slider 316 are movable on the first decoupling rail 310, and a first decoupling linkage 314 and a second decoupling linkage 318 fasten to the first slider 312 and the second slider 316 respectively. However, the second decoupling slider 316, the fourth slider 326, the second decoupling linkage 318 and the fourth decoupling linkage 238 can be removed, if necessary.

Please refer to FIG. 10C, wherein two linear motors are provided for a second linkage movable in the second direction. A third rail 230 is below the third coils 132 and the fourth rail 240 is below the coils 142. A fifth slider 232 and a sixth slider 234 are movable on the third rail 230. A fifth plurality of magnets 134 and a sixth plurality of magnets 136, facing to the third coils 132, fasten to the fifth slider 232 and the sixth slider 234 respectively. A seventh slider 242 and an eighth slider 244 are movable on the fourth rail 240. A seventh plurality of magnets 144 and an eighth plurality of magnets 146, facing to the fourth coils 124, fasten to the seventh slider 242 and the eighth slider 244 respectively. A second linkage 256 has two arms with an opening. One end of the second linkage 256 fastens to the fifth slider 232 and the sixth slider 234, and the other end of the second linkage 256 fastens to the seventh slider 242 and the eighth slider 244.

Please refer to FIG. 10D, wherein two decoupling rails are mounted on the second linkage 256. The third decoupling rail 330 is mounted on one are of the second linkage 256 and the fourth decoupling rail 340 is mounted on the other arm of the second linkage 256. A fifth slider 332 is movable on the third decoupling rail 330, and a sixth decoupling linkage 334 fastens to the fourth slider 340. A table is thus fastened to the all decoupling linkages 314/318/324/328/334/344, and a x-y stage is thus provided.

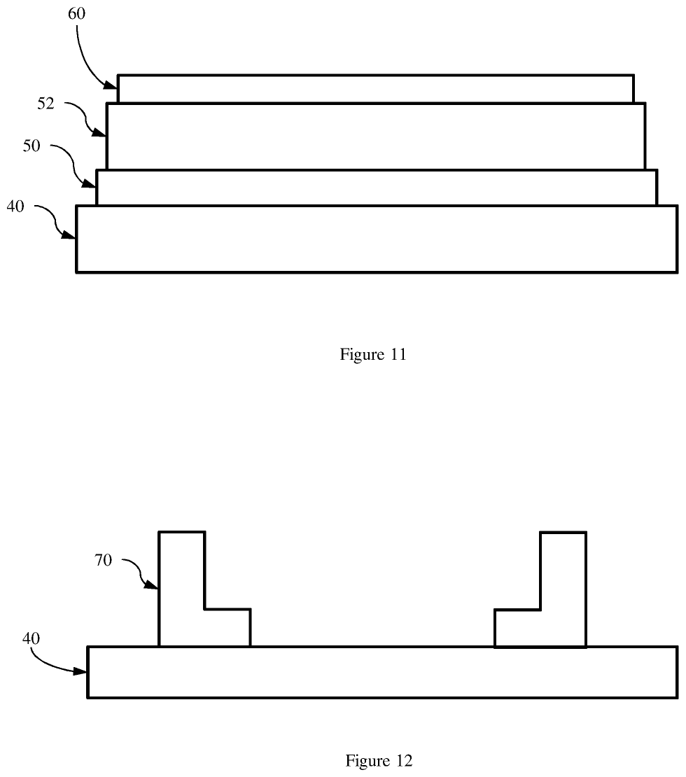

In most applications, some other functions for moving the table additional to the x-y moving can be applied to the present invention, as shown in FIG. 11 and FIG. 12. If the height of a sample on the table should be adjustable, a z-stage 50 can be mounted on the table 40 of the x-y stage of the present invention. If the sample should be rotated in an angle, a theta stage 52 thus can be mounted on the table 40 of on the z-stage 50. When the stage is applied in the semiconductor manufacturing industry, an E chuck 60 is necessary for holding a wafer. Thus, the E chuck 60 can be mounted on the table 40, z-stage 50, or theta stage 52. A jig 70 can be mounted on the table 40 for handling an article to be operated in the vacuum chamber. For example, if a FOUP should be inspected by using SEM, a jig 70 can be mounted on the table 40 for holding the FOUP.

In the present invention, there is no movable cable for linear motor to generate particles in vacuum environment. Further, heats generated by coils can be transferred outside directly by thermal conduction through the wall of vacuum chamber, thereby no cooling system for the coils. In the present invention, there is only one table for x-y stage, which provides a thinner stage. Moreover, loads of the linear motors along two directions orthogonal with each other are very close, and there is no cross-loading for linear motors on the counter direction. Thus, the nature frequency of the linear motors on the two directions are close, and response of the linear motors on the two directions are close, thereby improving interpolation motion of the table. The accuracy of curve motion of the x-y stage can in this invention be enhanced further.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A linear motor in a vacuum chamber, comprising:
a stator fastened to a wall of the chamber and configured by a plurality of coils which is arranged along a first direction; and
a mover, coupled to the stator, being configured by a plurality of magnets and moving along the first direction, wherein heats generated by the plurality of coils are conducted outside the vacuum chamber through the wall.

2. A monitoring device for measuring the linear motor in claim 1, comprising:
a scale fastened on the mover; and
a read head fastened on the wall to read the scale such that a position of the mover can be obtained.

3. A stage in a chamber, comprising:
a first linear motor, fastened to the chamber, providing a first movement along a first direction;
a first linkage coupled to the first linear motor, such that the first linkage moves in the first direction;
a second linear motor, fastened to the chamber, providing a second movement along a second direction orthogonal to the first direction;
a second linkage coupled to the second linear motor, such that the second linkage moves along the second direction;
a decoupling member coupled to the first linkage and the second linkage, such that the decoupling member can be moved in the first direction and the second direction; and
a table fastened to the decoupling member.

4. The stage according to claim 3, wherein said first linear motor includes first coils as a first stator fastened to a first high thermal conductive material, and said second linear motor includes second coils as a second stator fastened to a second high thermal conductive material, wherein said first high thermal conductive material and said second high thermal conductive material fasten to the chamber.

5. The stage according to claim 4, wherein said first linear motor includes a first mover configured by a first plurality magnet, and said second linear motor includes a second mover configured by a second plurality of magnets.

6. The stage according to claim 5, wherein said first linkage couple to the first mover, and said second linkage couples to the second mover.

7. The stage according to claim 6, further comprising a z-stage on the table.

8. The stage according to claim 6, further comprising a theta stage on the table.

9. The stage according to claim 6, further comprising an electrostatic chuck on the table.

10. The stage according to claim 6, further comprising a jig on the table.

11. A stage in a vacuum chamber, comprising:
a first linear motor and a second linear motor provide a first movement along a first direction, said first linear motor and said second linear motor including a first plurality of coils fastened on a first wall of the vacuum chamber and a second plurality of coils fastened on a second wall of the vacuum chamber respectively;
a first linkage coupled to a first mover of the first linear motor and a second mover of the second linear motor;
a third linear motor and a fourth linear motor provide a second movement along a second direction orthogonal to the first direction, said third linear motor and said fourth linear motor including a third plurality of coils fastened on a third wall of the vacuum chamber and a fourth plurality of coils fastened on a fourth wall of the vacuum chamber respectively;
a second linkage coupled to a third mover of the third linear motor and a fourth mover of the fourth linear motor;
a decoupling member, coupled to the first linkage and the second linkage; and
a table fastened to the decoupling member.

12. The stage according to claim 11, wherein said first linear motor, said second linear motor, said third linear motor, and said fourth linear motor include a first fixed rail and a first slider thereon, a second fixed rail and a second slider thereon, a third fixed rail and two third sliders thereon, and a fourth fixed rail and two fourth sliders thereon respectively, wherein one end of said first linkage fastens to one side of the first slider and a first mover of said first linear motor fastens to the other side of the first slider, and the other end of said first linkage fastens to one side of the second slider and a second mover of said second linear motor fastens to the other side of the second slider.

13. The stage according to claim 12, wherein each of said two third sliders has one side fastened to two third movers of the third linear motor respectively and has the other side fastened to one end of the second linkage, and each of said two fourth sliders has one side fastened to two fourth movers of the third linear motor respectively and has the other side fastened to the other end of the second linkage.

14. The stage according to claim 13, wherein the second linkage includes a first arm and a second arm parallel with each other.

15. The stage according to claim 14, wherein said decoupling member includes:
a first decoupling rail, fastened to the first linkage and moveable along the first direction, providing the second movement along the second direction;
a first decoupling slider moving freely on the first decoupling rail;
a first decoupling linkage fastened on the first decoupling slider;
a second decoupling rail and a third decoupling rail, fastened on the first arm and the second arm respectively and both moveable along the second direction, providing the first movement along the first direction;
a second decoupling slider and a third decoupling slider moving on the second decoupling rail, and a fourth decoupling slider and a fifth decoupling slider on the third decoupling rail; and
a second decoupling linkage and a third decoupling linkage fastened on the second decoupling slider and the third decoupling slider respectively, and a fourth decoupling linkage and a fifth decoupling linkage fastened on the fourth decoupling slider and the fifth decoupling slider respectively.

16. The stage according to claim 15, wherein said table fastens to the first decoupling linkage, the second decoupling linkage, the third decoupling linkage, the fourth decoupling linkage, and the fifth decoupling linkage.

17. The stage according to claim 11, wherein said decoupling member includes:
a first decoupling rail, coupled to said first linear motor and said second linear motor, moveable along the first direction;
a first decoupling slider, on the first decoupling rail, moveable along the second direction;
a first decoupling linkage fastened on the first decoupling slider;
a second decoupling rail, coupled to said third linear motor and said fourth linear motor, moveable along the second direction;
a second decoupling slider, on the second decoupling rail, moveable along the first direction; and
a second decoupling linkage fastened on the second decoupling slider.

18. The stage according to claim 11, wherein the first linkage includes a first arm and a second arm parallel with each other, wherein said decoupling member includes:
a first decoupling rail and a second decoupling rail, fastened to the first arm and the second arm respectively and movable along the first direction, providing the second movement along the second direction;
a first decoupling slider and a second decoupling slider moving freely on the first decoupling rail and the second decoupling rail respectively; and
a first decoupling linkage fastened on the first decoupling slider, and a second decoupling linkage on the second decoupling slider.

19. The stage according to claim 18, wherein the second linkage includes a third arm and a fourth arm parallel with each other, wherein said decoupling member includes:
a third decoupling rail and a fourth decoupling rail, fastened on the third arm and the fourth arm respectively and both moveable along the second direction, providing the first movement along the first direction;
a third decoupling slider and a fourth decoupling slider moving on the third decoupling rail and the fourth decoupling rail respectively; and
a third decoupling linkage and a fourth decoupling linkage fastened on the third decoupling slider and the fourth decoupling slider respectively.

20. The stage according to claim 19, wherein said table fastens to the first decoupling linkage, the second decoupling linkage, the third decoupling linkage, and the fourth decoupling linkage.
